(19) United States
(12) Patent Application Publication
(10) Pub. No.: US 2025/0204193 A1
(43) Pub. Date: Jun. 19, 2025

(54) Light Emitting Display Device Having Improved Luminescent Property

(71) Applicant: LG Display Co., Ltd., Seoul (KR)

(72) Inventors: Da-Bin Kim, Paju-si (KR); Seung-Cheol You, Paju-si (KR); Seung-Ryong Lee, Paju-si (KR)

(21) Appl. No.: 18/921,830

(22) Filed: Oct. 21, 2024

(30) Foreign Application Priority Data
Dec. 15, 2023 (KR) 10-2023-0183108

(51) Int. Cl. H10K 59/38; H10K 50/115; H10K 50/19; H10K 59/126; H10K 102/00

(52) U.S. Cl. CPC H10K 59/38; H10K 50/115; H10K 50/19; H10K 59/126; H10K 2102/331

(57) ABSTRACT

A light emitting display device comprises a color conversion layer that converts light emitted from a light emitting diode to different colors and a light blocking layer disposed between the color conversion layers. Each of the color conversion layers and the light blocking layer comprise perovskite particles with different halogen composition. The loss of the emitted light can be minimized in case displaying different colors in different pixel regions. The luminance and color gamut of the light emitting display device can be maximized by introducing perovskite particles with narrow full-width at half maximum as well as beneficial color purity and luminous efficiency into the color conversion layer and the light blocking layer.

### CROSS-REFERENCE TO RELATED APPLICATIONS

This application claims priority under 35 U.S.C. § 119 (a) to the Republic of Korea Patent Application No. 10-2023-0183108, filed in the Republic of Korea on Dec. 15, 2023, the entire contents of which are hereby expressly incorporated by reference into the present application.

### BACKGROUND

### Technical Field

The present disclosure relates to a light emitting device, and more particularly to, a light emitting display device with beneficial luminous efficiency and color gamut.

### Discussion of Related Art

Flat display devices comprising a light emitting diode (LED) have been investigated as display devices that can replace a liquid crystal display device (LCD). The electrode configurations in the LED can implement unidirectional or bidirectional images. Also, the LED can be formed even on a flexible transparent substrate such as a plastic substrate so that a flexible or a foldable display device can be realized with ease using the LED. In addition, the LED can be driven at a lower voltage and the LED has advantageous high color purity compared to the LCD.

The LED emits light as holes injected from anode and electrons injected from cathode are recombined within an emitting material layer to generate excitons of unstable energy state, and the excitons convert to a stable ground state. As light generated in the LED emits outwardly, considerable amount of light loss can be occurred. As the luminous efficiency are lowered owing to the light loss, it is difficulty to realize intended colors.

### SUMMARY OF THE DISCLOSURE

Accordingly, some embodiments of the present disclosure are directed to a light emitting display device that substantially obviates one or more of the problems due to the limitations and disadvantages of the related art.

An aspect of the present disclosure is to provide a light emitting display device with beneficial luminance and color gamut as well as improved luminous efficiency.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a light emitting display device that comprises a first substrate having a first pixel region, a second pixel region and a third pixel region, each of the first pixel region, the second pixel region and the third pixel region comprising an emission area and a non-emission area; a light emitting diode disposed in each of the first pixel region, the second pixel region and the third pixel region and located at the emission area on the first substrate; a color conversion layer corresponding to each of the first pixel region, the second pixel region and the third pixel region and disposed on the light emitting diode or disposed between the first substrate and the light emitting diode; and a light blocking layer disposed at each of the non-emission area between the color conversion layer, wherein the color conversion layer comprises a first color conversion layer disposed correspondingly to the emission area of the first pixel region, a second color conversion layer disposed correspondingly to the emission area of the second pixel region and a third color conversion layer disposed correspondingly to the emission area of the third pixel region, wherein the first color conversion layer comprises perovskite particles represented by the following Chemical Formula 2, wherein the second color conversion layer comprises perovskite particles represented by the following Chemical Formula 3, wherein the third color conversion layer comprises perovskite particles represented by the following Chemical Formula 4 or Chemical Formula 5, and wherein the light blocking layer comprises perovskite particles represented by the following Chemical Formula 6:

AM(Br)₍₃₋ₐ₎Iₐ [Chemical Formula 2]

AMBr₃ [Chemical Formula 3]

AMCl₃ [Chemical Formula 4]

AM(Br)₍₃₋ₐ₎Clₐ [Chemical Formula 5]

AMI₃ [Chemical Formula 6]
wherein, in Chemical Formulae 2 to 6,
A is an organic ammonium or an alkali metal;
M is metal selected from a bivalent transition metal, a rare earth metal, an alkaline earth metal, Pb, Sn, Ge, Ga, In, Al, Sb, Bi, Po, and combinations thereof; and
0<a<3.

In one embodiment, the light emitting diode can emit white light.

The light emitting display device can further comprise a color filter layer disposed between the light emitting diode disposed at the emission area of the third pixel region and the third color conversion layer.

The third color conversion layer can comprise the perovskite particles represented by Chemical Formula 4.

In another embodiment, the first substrate can further comprise a fourth pixel region.

The color conversion layer can further comprise a fourth color conversion layer disposed respectively to an emission area of the fourth pixel region.

As an example, the fourth color conversion layer can comprise the perovskite particles represented by Chemical Formula 4.

In another embodiment, the light emitting diode can emit blue light.

The third color conversion layer can comprise the perovskite particles represented by Chemical Formula 5.

As an example, “A” in Chemical formulae 2 to 6 can comprise organic ammonium.

In another embodiment, “A” in Chemical Formulae 2 to 6 can be methyl ammonium, ethyl ammonium, formamidinium, Cs, or Rb.

In another embodiment, “M” in Chemical Formulae 2 to 6 can be Pb, Sn, or Ge.

As an example, the light emitting diode can comprises a first electrode; a second electrode facing the first electrode; and an emissive layer disposed between the first electrode and the second electrode, and comprising at least one emitting material layer.

In one embodiment, the emitting material layer can comprise organic emission material.

Alternatively, the emitting material layer can comprise inorganic luminescent particles.

The light emitting display device can further comprise a thin film transistor disposed on the first substrate corresponding to each of the first pixel region, the second pixel region and the third pixel region and connected to the light emitting diode corresponding to each of the first pixel region, the second pixel region and the third pixel region.

In one or more embodiments, each color conversion layer disposed in each pixel region and light blocking layer disposed between the color conversion layers includes perovskite particles with various or different halogen composition. It is possible to emit externally different colors as the pixel region from the display device by introducing the perovskite particles with different emitting colors by the halogen atom compositions into the color conversion layers and the light blocking layers.

The light loss emitted from the light emitting diode can be minimized by introducing the perovskite particles into the color conversion layers and the light blocking layers. The luminance and the color gamut of the light emitting display device can be maximized by introducing the perovskite particles with beneficial color purity owing to its narrow full-width at half maximum (FWHM) as well as beneficial luminous efficiency.

Environment-friendly light emitting display device can be manufactured as the power consumption of the device can be lowered. Therefore, it is possible to fabricate a light emitting display device that can implement ESG (environmental, social and Governance) idea by applying the present disclosure.

It is to be understood that both the foregoing general description and the following detailed description are exemplary and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates a schematic circuit diagram of a light emitting display device in accordance with one or more embodiments of the present disclosure.

FIG. 2 illustrates a cross-sectional view of a light emitting display device in accordance with an embodiment of the present disclosure.

FIG. 3 illustrates a cross-sectional view of a light emitting diode having multiple emitting parts in accordance with an embodiment of the present disclosure.

FIG. 4 is a schematic diagram illustrating dispositions of a light emitting diode, a color conversion layer and a color filter layer in each pixel region of the light emitting display device in accordance with an embodiment of the present disclosure.

FIGS. 5A to 5C are schematic drawings illustrating a process of color conversion layers and light blocking layers comprising perovskite particles with various or different halogen compositions in accordance with an embodiment of the present disclosure.

FIG. 6 illustrates a cross-sectional view of a light emitting display device in accordance with another embodiment of the present disclosure.

FIG. 7 illustrates a cross-sectional view of a light emitting diode having a single emitting part in accordance with another embodiment of the present disclosure.

FIG. 8 is a schematic diagram illustrating dispositions of a light emitting diode, a color conversion layer and a color filter layer in each pixel region of the light emitting display device in accordance with another embodiment of the present disclosure.

FIGS. 9A to 9C are schematic drawings illustrating a process of color conversion layers and light blocking layers comprising perovskite particles with various or different halogen compositions in accordance with another embodiment of the present disclosure.

FIG. 10 illustrates a cross-sectional view of a light emitting diode having multiple emitting parts in accordance with another embodiment of the present disclosure.

FIG. 11 is a schematic diagram illustrating dispositions of a light emitting diode, a color conversion layer and a color filter layer in each pixel region of the light emitting display device in accordance with another embodiment of the present disclosure.

FIGS. 12A to 12E are schematic drawings illustrating a process of color conversion layers and light blocking layers comprising perovskite particles with various or different halogen compositions in accordance with another embodiment of the present disclosure.

FIG. 13 is a photograph showing optical images in visible ranges of perovskite particles synthesized in an Example of the present disclosure.

FIG. 14 is a photograph showing optical images and photoluminescence (PL) colors in visible ranges of MAPbBr₃ perovskite particles synthesized in an Example of the present disclosure.

Each of FIGS. 15 and 16 illustrates light transmittance and reflectivity of black perovskite particles MAPbI₃ synthesized in an Example of the present disclosure.

FIG. 17 illustrates PL spectra for lights transmitting each of color conversion layers in which perovskite particles synthesized in an Example of the present disclosure are coated.

### DETAILED DESCRIPTION OF THE EMBODIMENTS

Reference will now be made in detail to aspects of the disclosure, examples of which are illustrated in the accompanying drawings. Wherever possible, the same reference numbers will be used throughout the drawings to refer to the same or like parts.

All the components of each light emitting display device according to all embodiments of the present disclosure are operatively coupled and configured.

The present disclosure relates to a light emitting display device that comprises light emitting diodes and color conversion layers disposed in an emission areas of multiple pixel regions and light blocking layers disposed between color conversion layers, and the color conversion layers and the light blocking layer comprises perovskite particles with various or different halogen atom compositions. The light emitting display device in accordance with the present disclosure will be described.

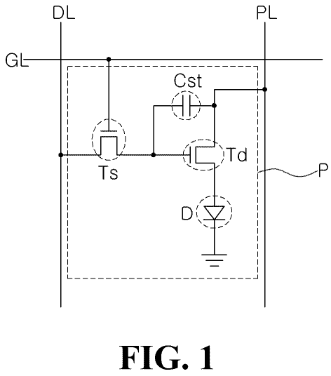

FIG. 1 illustrates a schematic circuit diagram of a light emitting display device in accordance with one or more embodiments of the present disclosure.

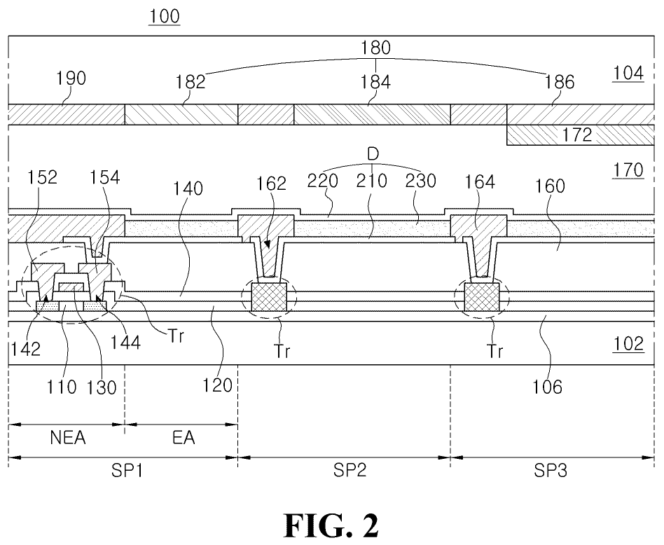

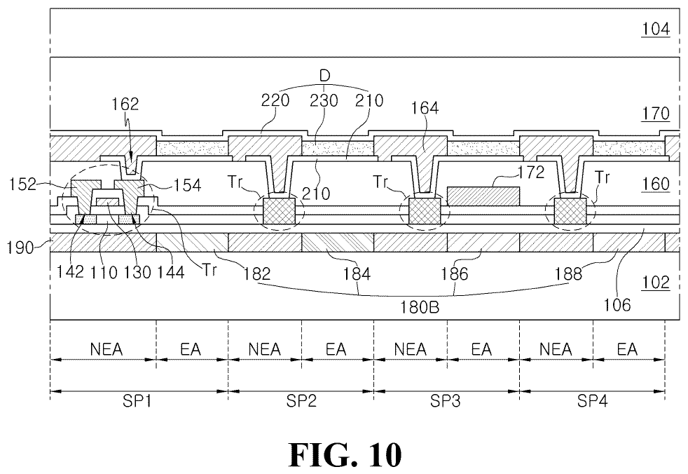

As illustrated in FIG. 1, a gate line GL, a data line DL and power line PL, each of which crosses each other to define a pixel region P, are provided in a light emitting display device. A switching thin film transistor Ts, a driving thin film transistor Td, a storage capacitor Cst and a light emitting diode D are disposed within the pixel region P. The pixel region P can comprise a first pixel region SP1 (FIG. 2), a second pixel region SP2 (FIG. 2) and a third pixel region SP3 (FIG. 2), and optionally a fourth pixel region SP4 (FIG. 10). However, embodiments of the present disclosure are not limited to such examples. The light emitting display device can comprise a plurality of such pixel regions P which can be arranged in a matrix configuration or other configurations.

The switching thin film transistor Ts is connected to the gate line GL and the data line DL. The driving thin film transistor Td and the storage capacitor Cst are connected between the switching thin film transistor Ts and the power line PL. The light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

The driving thin film transistor Td is turned on by the data signal applied to a gate electrode 130 (FIG. 2) so that a current proportional to the data signal is supplied from the power line PL to the light emitting diode D through the driving thin film transistor Td. And then, the light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the light emitting display device can display a desired image.

FIG. 2 illustrates a schematic cross-sectional view of a light emitting display device in accordance with an embodiment of the present disclosure. The pixel circuit configuration of FIG. 1 can be used in the display device of FIG. 2 or other figures of the present application.

As illustrated in FIG. 2, the light emitting display device 100 comprises a first substrate 102 and a second substrate (or encapsulation film) 104 facing the first substrate 102. The first to third pixel regions SP1, SP2 and SP3 are defined in the first substrate 102 and/or the second substrate 104. Each of the first pixel region SP1, the second pixel region SP2 and the third pixel region SP3 can be divided into an emission area EA where a light emitting diode D and a color conversion layer 180, and optionally a color filter layer 172 are disposed, and a non-emission area NEA where a thin film transistor Tr and a light blocking layer 190 are disposed. As an example, each of the first pixel region SP1, the second pixel region SP2 and the third pixel region SP3 can be a red (R) pixel region, a green (G) pixel region and a blue (B) pixel region, respectively.

A thin film transistor Tr and a light emitting diode D are disposed on the first substrate 102 in the first to third pixel regions SP1, SP2 and SP3 to from an array substrate. A color conversion layer 180 is disposed in the emission area EA under the second substrate 104 defining the first to third pixel regions SP1, SP2 and SP3, and a light blocking layer 190 is disposed in each of the non-emission area NEAs between color conversion layers 182, 184 and 186.

Each of the first substrate 102 and the second substrate 104 can include a transparent material. For example, each of the first substrate 102 and the second substrate 104 can be a glass substrate, a flexible substrate, a polymer plastic substrate or a metal foil. As an example, the flexible substrate can include polyimide (PI), polyethersulfone (PES), polyethylenenaphthalate (PEN), polyethylene terephthalate (PET), polycarbonate (PC) and/or combinations thereof.

A buffer layer 106 can be disposed on the first substrate 102 in the first to third pixel regions SP1, SP2 and SP3. The thin film transistor Tr can be disposed on the buffer layer 106. In certain embodiments, the buffer layer 106 can be omitted.

A semiconductor layer 110 is disposed on the buffer layer 106. In one embodiment, the semiconductor layer 110 can comprise, but is not limited to, oxide semiconductor materials. In this case, a light-shield pattern can be disposed under the semiconductor layer 110, and the light-shield pattern can prevent light from being incident toward the semiconductor layer 110, thereby, preventing or reducing the semiconductor layer 110 from being degraded by the light. Alternatively, the semiconductor layer 110 can comprise polycrystalline silicon. In this case, opposite edges of the semiconductor layer 110 can be doped with impurities.

A gate insulating layer 120 comprising an insulating material is disposed on the semiconductor layer 110. The gate insulating layer 120 can comprise, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on the entire area of the first substrate 102 as shown in FIG. 2, the gate insulating layer 120 can be patterned identically as the gate electrode 130.

An interlayer insulating layer 140 comprising an insulating material is disposed on the gate electrode 130 and covers an entire surface of the first substrate 102. The interlayer insulating layer 140 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 and the interlayer insulating layer 140 in FIG. 2. Alternatively, in certain embodiments, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon.

The light emitting diode D is electrically connected to the thin film transistor Tr as a driving element in the first to third pixel regions SP1, SP2 and SP3. In addition, the switching thin film transistor Ts (FIG. 1) electrically connected to the thin film transistor Tr, the gate line GL (FIG. 1) and the data line DL (FIG. 1), and the storage capacitor Cst (FIG. 1) electrically connected to the switching thin film transistor Ts and the power line PL (FIG. 1) are disposed on the first substrate 102 in the first to third pixel regions SP1, SP2 and SP3.

When the switching thin film transistor Ts is turned on by a gate signal applied to the gate line GL, a data signal applied to the data line DL is applied to the gate electrode 130 of the thin film transistor Tr as the driving element and one electrode of the storage capacitor Cst through the switching thin film transistor Ts.

The thin film transistor Tr is turned on by the data signal applied to the gate electrode 130 so that a current proportional to the data signal is supplied from the power line PL to the light emitting diode D through the thin film transistor Tr of the driving element. And then, the light emitting diode D emits light having a luminance proportional to the current flowing through the thin film transistor Tr.

A passivation layer 160 is disposed on the source and drain electrodes 152 and 154. The passivation layer 160 covers the thin film transistor Tr on the entire first substrate 102. The passivation layer 160 has a flat top surface and a drain contact hole (or a contact hole) 162 that exposes or does not cover the drain electrode 154 of the thin film transistor Tr.

The light emitting diode (LED) D comprises a first electrode 210 that is disposed on the passivation layer 160 and connected to the drain electrode 154 of the thin film transistor Tr. The LED D further comprises an emissive layer 230 and a second electrode 220 each of which is disposed sequentially on the first electrode 210.

One of the first electrode 210 and the second electrode 220 can be an anode, and the other of the first electrode 210 and the second electrode 220 can be a cathode. One of the first electrode 210 and the second electrode 220 can be a reflective electrode, and the other of the first electrode 210 and the second electrode 220 can be a transmissive electrode.

The first electrode 210 is disposed separately in each pixel region SP1, SP2 or SP3. In one embodiment, the first electrode 210 can be an anode and comprise conductive material having relatively high work function value. For example, the first electrode 210 can comprise a transparent conductive oxide (TCO).

In one embodiment, when the light emitting display device 100 is a bottom-emission type, the first electrode 210 can have a single-layered structure of the TCO. Alternatively, when the light emitting display device 100 is a top-emission type, a reflective electrode or a reflective layer can be disposed under the first electrode 210. For example, the reflective electrode or the reflective layer can comprise, but is not limited to, silver (Ag) or aluminum-palladium-copper (APC) alloy. As an example, in the LED D of the top-emission type, the first electrode 210 can have a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region SP1, SP2 or SP3. In certain embodiments, the bank layer 164 can be omitted.

An emissive layer 230 is disposed on the first electrode 210. In one embodiment, the emissive layer 230 can have a single-layered structure of an emitting material layer (EML). In one embodiment, the EML can comprise organic emitting materials such as host and/or dopant. In another embodiment, the EML can comprise inorganic luminescent particles such as quantum dots (QDs) and/or quantum rods (QRs). For example, the organic dopant can comprise phosphorescent material, fluorescent material and/or delayed fluorescent material emitting red (R) color, green (G) color and blue (B) color. The LED D can emit white (W) color.

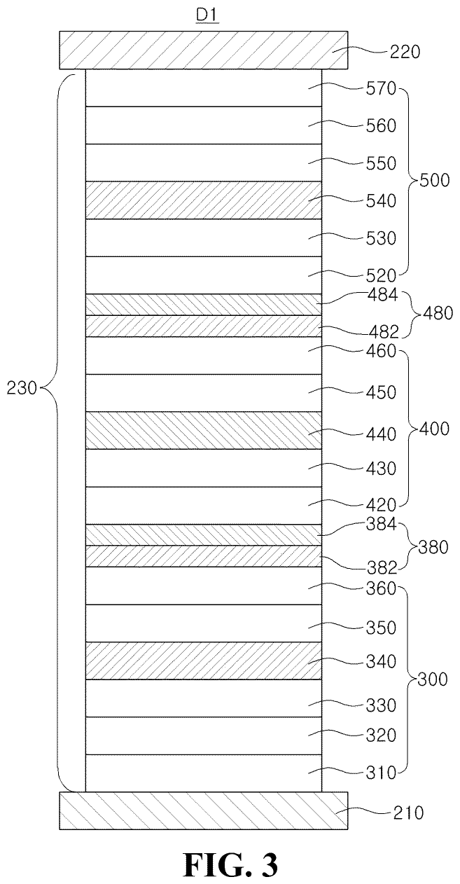

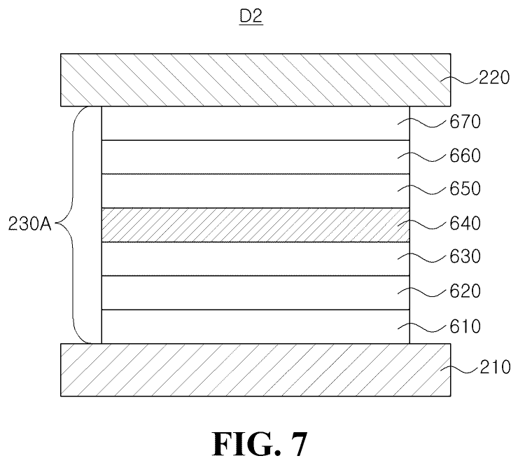

In another embodiment, the emissive layer 230 can have a multiple-layered structure. For example, the emissive layer 230 can further comprise a hole injection layer (HIL), a hole transport layer (HTL) and/or an electron blocking layer (EBL) disposed sequentially between the first electrode 210 and the EML, and/or a hole blocking layer (HBL), an electron transport layer (ETL), an electron injection layer (EIL) and/or a charge generation layer (CGL) disposed between the EML and the second electrode 210 (FIGS. 3 and 7). Two or more emitting parts of the emissive layer 230 can form a tandem structure (FIG. 3), or the emissive layer 230 can consist of a single emitting part.

The second electrode 220 is disposed on the first substrate 102 above which the emissive layer 230 is disposed. The second electrode 220 can be disposed on the entire display area. The second electrode 220 can comprise a conductive material with a relatively low work function value compared to the first electrode 210. When the light emitting display device 100 is a top-emission type, the second electrode 220 is thin so as to have light-transmissive (semi-transmissive) property.

In addition, an adhesive layer 170 can be disposed on the LED D in order to prevent or reduce outer moisture from penetrating into the LED D. The adhesive layer 170 can comprise, but is not limited to, an optically clear adhesive (OCA) and a pressure sensitive adhesive (PSA).

In one embodiment, a color filter layer 172 is disposed under the color conversion layer 186 in the third pixel region SP3. The color filter layer 172 can comprise blue colorant. For example, the blue colorant comprises a blue pigment or a blue dye.

The color conversion layer 180 can comprise a first color conversion layer 182 disposed correspondingly to the emission area EA of the first pixel region SP1, a second color conversion layer 184 disposed correspondingly to the emission area EA of the second pixel region SP2, and a third color conversion layer 186 disposed correspondingly to the emission area EA of the third pixel region SP3. The light blocking layer 190 is disposed among the first to third color conversion layers 182, 184 and 186. The light blocking layers 190 are disposed correspondingly to each of the non-emission areas NEAs in the first to third pixel regions SP1, SP2 and SP3, and define the first to third pixel regions SP1, SP2 and SP3.

As described in more detail later, each of the first to third color conversion layers 182, 184 and 186 and the light blocking layer 190 comprises perovskite particles 182a, 184a, 186a and 192 with different halogen atom compositions. The color conversion layer 180 and the light blocking layer 190 includes the perovskite particles 182a, 184a, 186a and 192 with beneficial luminous efficiency and narrow full width at half maximum (FWHM) so that the light emitting display device 100 with improved luminance and color gamut can be implemented.

The second substrate 104 is disposed on the color conversion layer 180 and the light blocking layer 190 in order to prevent external moisture from penetrating into the LED D. In another embodiment, an encapsulation film can be disposed on the adhesive layer 170 over the entire first substrate 102. For example, the encapsulation film can have a laminated structure of, but is not limited to, a first inorganic insulating layer, an organic insulating layer and a second inorganic insulating layer. In certain embodiment, the encapsulation film can be omitted.

In addition, a cover window can be attached to the second substrate 104. In this case, the first substrate 102 and the cover window can have a flexible property, thus the light emitting display device 100 can be a flexible display device.

The LED that can be used in the light emitting display device in the first embodiment is described in more detail. FIG. 3 illustrates a schematic cross-sectional view of a light emitting diode having multiple emitting parts in accordance with an embodiment of the present disclosure. For instance, FIG. 3 shows an example (LED D1) of the LED D in FIGS. 1 and 2.

As illustrated in FIG. 3, the light emitting diode D1 in accordance with an example of the present disclosure comprises first and second electrodes 210 and 220 facing each other and an emissive layer 230 disposed between the first and second electrodes 210 and 220. The light emitting diode (LED) D1 can be disposed in the first to third pixel regions SP1, SP2 and SP3, and emits white (W) light.

One of the first electrode 210 and the second electrode 220 can be an anode, and the other of the first electrode 210 and the second electrode 220 can be a cathode. As an example, the first electrode 210 can be an anode and the second electrode 220 can be a cathode. One of the first electrode 210 and the second electrode 220 can be a transmissive electrode, and the other of the first electrode 210 and the second electrode 220 can be a reflective electrode.

The first electrode 210 can comprise transparent conductive oxide (TCO) with relatively high work function. As an example, the first electrode 210 can comprise, but is not limited to, doped or undoped metal oxide such as indium-tin-oxide (ITO), indium-zinc-oxide (IZO), indium-tin-zinc-oxide (ITZO), indium-copper-oxide (ICO), tin oxide (SnO₂), indium oxide (In₂O₃), cadmium: zinc oxide (Cd: ZnO), fluorine: tin oxide (F: SnO₂), indium: tin oxide (In: SnO₂), gallium: tin oxide (Ga: SnO₂) and aluminum: zinc oxide (Al: ZnO; AZO). Alternatively or additionally, the first electrode 210 can comprise metal material or non-metal material such as nickel (Ni), platinum (Pt), gold (Au), silver (Ag), iridium (Ir) and/or carbon nanotube (CNT).

The second electrode 220 can comprise metal or metal halide with relatively low work function. As an example, the second electrode 220 can comprise, but is not limited to, calcium (Ca), barium (Ba), calcium/aluminum (Ca/Al), lithium fluoride/calcium (LiF/Ca), lithium fluoride/aluminum (LiF/Al), barium fluoride/aluminum (BaF₂/Al), cesium fluoride/aluminum (CsF/Al), calcium carbonate/aluminum (CaCO₃/Al), barium fluoride/calcium/aluminum (BaF₂/Ca/Al), aluminum (Al), magnesium (Mg), aluminum/magnesium (Al/Mg), gold: magnesium (Au:Mg) and/or silver: magnesium (Ag:Mg). For example, each of the first electrode 210 and the second electrode 220 can have a thickness of, but is not limited to, about 30 nm to about 300 nm.

The emissive layer 230 can comprise a first emitting part 300, a second emitting part 400 and a third emitting part 500. In addition, the emissive layer 230 can further comprise a first charge generation layer (CGL1) 380 disposed between the first emitting part 300 and the second emitting part 400, and a second charge generation layer (CGL2) 480 disposed between the second emitting part 400 and the third emitting part 500. Therefore, the first emitting part 300, the CGL1 380, the second emitting part 400, the CGL2 480 and the third emitting part 500 are laminated sequentially on the first electrode 210.

The first emitting part 300 can comprise a first emitting material layer (lower emitting material layer, EML1) 340. The first emitting part 300 can further comprise at least one of a hole injection layer (HIL) 310 disposed between the first electrode 210 and the EML1 340, a first hole transport layer (HTL1) 320 disposed between the HIL 310 and the EML1 340, and a first electron transport layer (ETL1) 360 disposed between the EML1 340 and the CGL1 380. Alternatively or additionally, the first emitting part 300 can further comprise at least one of a first electron blocking layer (EBL1) 330 disposed between the HTL1 320 and the EML1 340 and a first hole blocking layer (HBL1) 350 disposed between the EML1 340 and the ETL1 360.

The second emitting part 400 can comprise a second emitting material layer (middle emitting material layer, EML2) 440. The second emitting part 400 can further comprise at least one of a second hole transport layer (HTL2) 420 disposed between the CGL1 380 and the EML2 440, and a second electron transport layer (ETL2) 460 disposed between the EML2 440 and the CGL2 480. Alternatively or additionally, the second emitting part 400 can further comprise at least one of a second electron blocking layer (EBL2) 430 disposed between the HTL2 420 and the EML2 440 and a second hole blocking layer (HBL2) 450 disposed between the EML2 440 and the ETL2 460.

The third emitting part 500 can comprise a third emitting material layer (upper emitting material layer, EML3) 540. The third emitting part 500 can further comprise at least one of a third hole transport layer (HTL3) 520 disposed between the CGL2 480 and the EML3 540, a third electron transport layer (ETL3) 560 disposed between the EML3 540 and the second electrode 220, and an electron injection layer (EIL) 570 disposed between the ETL3 560 and the second electrode 220. Alternatively or additionally, the third emitting part 500 can further comprise at least one of a third electron blocking layer (EBL3) 530 disposed between the HTL3 520 and the EML3 540 and a third hole blocking layer (HBL3) 550 disposed between the EML3 540 and the ETL3 560.

The CGL1 380 is disposed between the first emitting part 300 and the second emitting part 400. In other words, the first emitting part 300 is connected to the second emitting part 400 through the CGL1 380. The CGL1 380 can be a PN-junction charge generation layer where a first N-type charge generation layer (N-CGL1) 382 is connected to a first P-type charge generation layer (P-CGL1) 384. The N-CGL1 382 is disposed between the ETL1 360 and the HTL2 420, and the P-CGL1 384 is disposed between the N-CGL1 382 and the HTL2 420.

The CGL2 480 is disposed between the second emitting part 400 and the third emitting part 500. In other words, the second emitting part 400 is connected to the third emitting part 500 through the CGL2 480. The CGL2 480 can be a PN-junction charge generation layer where a second N-type charge generation layer (N-CGL2) 482 is connected to a second P-type charge generation layer (P-CGL2) 484. The N-CGL2 482 is disposed between the ETL2 460 and the HTL3 520, and the P-CGL2 484 is disposed between the N-CGL2 482 and the HTL3 520.

In one embodiment, at least one of the EML1 340, the EML2 440 and the EML3 540 can be a blue emitting material layer, and at least another of the EML1 340, the EML2 440 and the EML3 540 can be a red to green emitting material layer. Hereinafter, the LED D1 where each of the EML1 340 and the EML3 540 is a blue emitting material layer, and the EML2 440 is a red to green emitting material layer will be described in detail.

The HIL 310 facilitates hole injections to the EML1 340 from the first electrode 210. Each of the HTL1 320, the HTL2 420 and the HTL3 520 transfers holes to the EML1 340, the EML2 440 and the EML3 540, respectively. Each of the HTL1 320, the HTL2 420 and the HTL3 520 can independently comprise organic material or inorganic material.

In one embodiment, each of the EML1 340, the EML2 440 and the EML3 540 can independently organic emission material. For example, each of the EMl1 340 and the EML3 540 can independently comprise organic emission material emitting blue color, and the EML2 440 can comprise organic emission material emitting red to green) colors. In one embodiment, each of the EMI1 340 and the EML3 540 can independently comprise organic emission material emitting blue color, and the EML2 440 can comprise organic emission material emitting yellow green color.

When the EML1 340 and the EML3 540 comprises the organic emission material, each of the EML1 340 and the EML3 540 can comprise a host and a blue dopant. The blue dopant can comprise at least one of blue phosphorescent material, blue fluorescent material and blue delayed fluorescent material.

When the EML2 440 comprises the organic emission material, the EML2 440 can comprise a host, a red dopant and a green dopant. The red dopant can comprise at least one of red phosphorescent material, red fluorescent material and red delayed fluorescent material. The green dopant can comprise at least one of green phosphorescent material, green fluorescent material and green delayed fluorescent material.

In another embodiment, each of the EML1 340, the EML2 440 and the EML3 540 can comprise inorganic luminescent particles. For example, the inorganic luminescent particles can comprise nano inorganic luminescent particles such as quantum dots (QDs) and quantum rods (QRs). The QDs and QRs are nano inorganic particles that emit light as electrons in an unstable state fall from the conduction band energy level to the valence band energy level.

In one embodiment, the inorganic luminescent particles can have a single structure. In another embodiment, the inorganic luminescent particles can have a heterogeneous structure of core/shell, and can comprise plural organic ligands that are bound to the surface of the core or free from the inorganic luminescent particles. In this case, the shell can consist of one shell or comprise plural shells.

As an example, each of the EML1 340 and the EML3 540 can comprise quantum dots and/or quantum rods emitting blue light, and the EML2 440 can comprise quantum dots and/or quantum rods emitting red to green lights. In some embodiments, each of the EML1 340 and the EML3 540 can comprise quantum dots and/or quantum rods emitting blue light, and the EML2 440 can comprise quantum dots and/or quantum rods emitting yellow-green light.

Each of the ETL1 360, the ETL2 460 and the ETL3 560 transfers electrons to the EML1 340, the EML2 440 and the EML3 540, respectively. Each of the ETL1 360, the ETL2 460 and the ETL3 560 can independently comprise organic material or inorganic material. The ETIL 570 facilitates electron injections to the EML3 540 from the second electrode 220.

In FIG. 3, the LED D1 where three emitting parts 300, 400 and 500 form a tandem structure is illustrated, but the light emitting diode with a tandem structure is not limited thereto. As an example, an emissive layer constituting a light emitting diode with a tandem structure can consist of a first emitting part emitting blue light, a second emitting part emitting red to green lights, and a charge generation layer disposed between the first emitting part and the second emitting part. In some embodiments, an emissive layer constituting a light emitting diode with a tandem structure can consist of a first emitting part emitting blue light, a second emitting part emitting yellow green light. In another embodiment, the light emitting diode with the tandem structure can have four or more emitting parts. In this case, at least one emitting part can emit blue light, at least another emitting part can emit green light, and at least another emitting part can emit red light. If necessary, another emitting part can emit yellow green light.

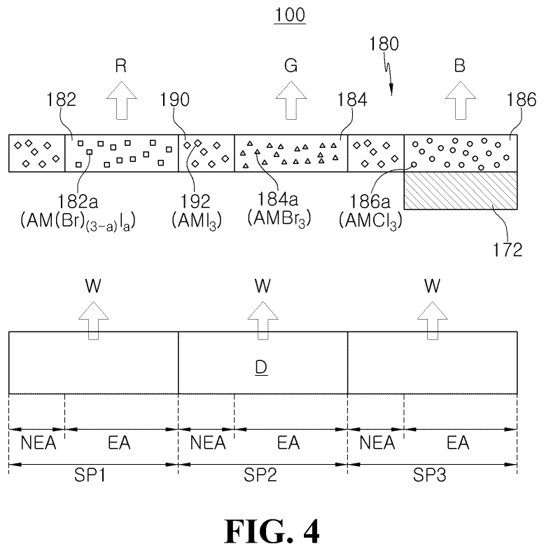

The constructions of the color conversion layer 180 and the light blocking layer 190 each of which includes the perovskite particles in the light emitting display device will be described in more detail. FIG. 4 is a schematic diagram illustrating dispositions of a light emitting diode, a color conversion layer and a color filter layer in each pixel region of the light emitting display device in accordance with an embodiment of the present disclosure. In FIGS. 4 to 12E, R indicates a red color, G indicates a green color, B indicates a blue color and W indicates a white color.

As illustrated in FIG. 4, the LED D emits a white (W) light. Each of the first color conversion layer 182, the second color conversion layer 184 and the third color conversion layer 186 is disposed correspondingly the emission area EA of the first to third pixel regions SP1, SP2 and SP3, respectively. In addition, each of the light blocking layers 190 is disposed correspondingly the non-emission area NEA of the first to third pixel regions SP1, SP2 and SP3, respectively. The color filter layer 172 can be disposed between the LED D and the third color conversion layer 186 correspondingly to the emission area EA of the third pixel region SP3.

Each of the first color conversion layer 182, the second color conversion layer 184, the third color conversion layer 186 and the light blocking layer 190 comprises a first perovskite particle 182a, a second perovskite particle 184a, a third perovskite particle 186a and a fifth perovskite particle 192, respectively, with different halogen atom compositions.

The perovskite particle 182a, 184a, 186a or 192 is a luminescent particle where a mono valent cation, bivalent metal cation and halide anion are linked. The perovskite particle 182a, 184a, 186a and 192 can have the following structure of Chemical Formula 1:

AMX₃ [Chemical Formula 1]
wherein, in Chemical Formula 1,
A is an organic ammonium or an alkali metal;
M is a metal selected from a bivalent transition metal, a rare earth metal, an alkaline earth metal, Pb, Sn, Ge, Ga, In, Al, Sb, Bi, Po, and combinations thereof; and
X is a halogen selected from the group consisting of Cl, Br, I, and combinations thereof.

For example, when “A” in Chemical Formula 1 is an organic ammonium, each of the perovskite particles 182a, 184a, 186a and 192 can have an organic-inorganic hybrid perovskite structure. The organic ammonium constituting the “A” in Chemical Formula 1 can comprise, but is not limited to, an amidinium-containing organic ion such as formamidinium, (CH₃NH₃)ₙ, ((CₓH₂ₓ₊₁)ₙNH₃)₂(CH₃NH₃)ₙ, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂) (where, n is an integer of 1 or more; x is an integer of 1 or more). As an example, the organic ammonium can be an unsubstituted or substituted C₁-C₁₀ alkyl ammonium. For example, the organic ammonium constituting “A” in Chemical Formula 1 can be methyl ammonium or ethyl ammonium.

In another embodiment, the alkali metal constituting “A” in Chemical Formula 1 can comprise, but is not limited to, Na, K, Rb, Cs and/or Fr. In this case, each of the perovskite particles 182a, 184a, 186a and 192 can have an inorganic metal perovskite structure.

As an example, when each of the perovskite particles 182a, 184a, 186a and 192 has the organic-inorganic hybrid perovskite structure, the organic-inorganic perovskite has a layered structure in which the inorganic plane where the metal cation is located is sandwiched between the organic planes where the organic cation is located. In this case, excitons are confined within the inorganic planes constituting the organic-inorganic hybrid perovskite structure owing to large difference in dielectric constant between the organic and inorganic materials, which has the advantage of emitting light with high color purity. In addition, when each of the perovskite particles 182a, 184a, 186a and 192 has the inorganic perovskite structure, it can be advantageous in terms of material stability.

In one embodiment, “A” in Chemical Formula 1 can be, but is not limited to, methyl ammonium (MA), ethyl ammonium, formamidinium (FA), Cs or Rb. In another embodiment, “M” in Chemical Formula 1 can be, but is not limited to, Pb, Sn or Ge.

The first color conversion layer 182, which is disposed correspondingly to the emission area EA of the first pixel region SP1 of the red (R) pixel region, comprises the first perovskite particle 182a in which X, a halogen atom in Chemical Formula 1, is a combination of iodine (I) and bromine (Br). The first perovskite particle 182a can be represented by the following Chemical Formula 2, referring to Chemical Formula 1.

AM(Br)₍₃₋ₐ₎Iₐ [Chemical Formula 2]
wherein, in Chemical Formula 2,
each of A and M is as defined in Chemical Formula 1; and
0<a<3.

The first perovskite particle 182a having the structure of Chemical Formula 2 emits red (R) light. Accordingly, the white (W) light emitted from LED D passes through the first color conversion layer 182 comprising the first perovskite particle 182a and emits red (R) light.

The second color conversion layer 184, which is disposed correspondingly to the emission area EA of the second pixel region SP2 of the green (G) pixel region, comprises the second perovskite particle 184a in which X, a halogen atom in Chemical Formula 1, is bromine (Br). The second perovskite particle 184a can be represented by the following Chemical Formula 3, referring to Chemical Formula 1.

AMBr₃ [Chemical Formula 3]
wherein, in Chemical Formula 3,
   each of A and M is as defined in Chemical Formula 1.

The second perovskite particle 184a having the structure of Chemical Formula 3 emits green (G) light. Accordingly, the white (W) light emitted from LED D passes through the second color conversion layer 184 comprising the second perovskite particle 184a and emits green (G) light.

In one embodiment, the third color conversion layer 186, which is disposed correspondingly to the emission area EA of the third pixel region SP3 of the blue (B) pixel region, comprises the third perovskite particle 186a in which X, a halogen atom in Chemical Formula 1, is chlorine (Cl). The third perovskite particle 186a can be represented by the following Chemical Formula 4, referring to Chemical Formula 1.

AMCl₃ [Chemical Formula 4]
wherein, in Chemical Formula 4,
each of A and M is as defined in Chemical Formula 4.

The third perovskite particle 186a having the structure of Chemical Formula 4 emits white (W) or transparent light.

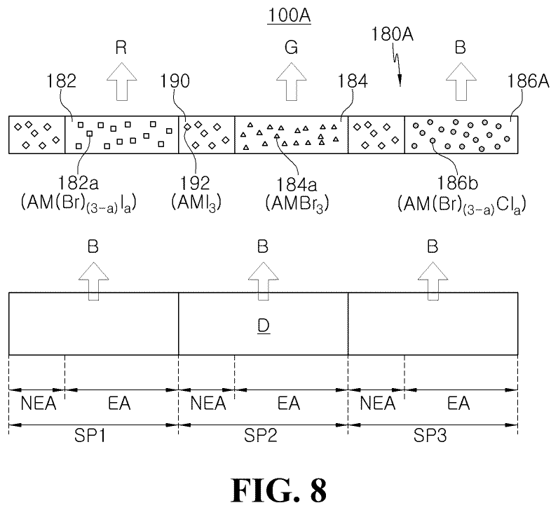

In another embodiment, the third color conversion layer 186, which is disposed correspondingly to the emission area EA of the third pixel region SP3 of the blue (B) pixel region, comprises a fourth perovskite particle 186b (FIG. 8) in which X, a halogen atom in Chemical Formula 1, is a combination of chlorine (Cl) and bromine (Br). The fourth perovskite particle 186b can be represented by the following Chemical Formula 5, referring to Chemical Formula 1.

AM(Br)₍₃₋ₐ₎Clₐ [Chemical Formula 5]
wherein, in Chemical Formula 5,
each of A and M is as defined in Chemical Formula 1; and
0<a<3.

The fourth perovskite particle 186b having the structure of Chemical Formula 5 emits blue (B) light.

In addition, the color filter layer 172 comprising blue colorant can be disposed correspondingly to the emission area (EA) of the third pixel region SP3 of the blue (B) pixel region. The white (W) light emitted from the LED D passes through the color filter layer 172, and only blue (B) light is transmitted. The blue (B) light transmitted through the color filter layer 172 passes through the third color conversion layer 186 comprising the third perovskite particle 186a or the fourth perovskite particle 186b and emits blue (B) light.

The light blocking layers 190, each of which is disposed correspondingly to the non-emission area NEA of the first to third pixel regions SP1, SP2 and SP3 of the non-transmissive region, comprises the fifth perovskite particle 192 in which X, a halogen atom in Chemical Formula 1, is an iodine (I). The fifth perovskite particle 192 can be represented by the following Chemical Formula 6, referring to Chemical Formula 1.

AMI₃ [Chemical Formula 6]
wherein, in Chemical Formula 6,
each of A and M is as defined in Chemical Formula 1.

The fifth perovskite particle 192 having the structure of Chemical Formula 6 is a black particle absorbing all visible light. Accordingly, the white (W) light emitted from LED D cannot pass through the light blocking layer 190 comprising the fifth perovskite particle 192.

Accordingly, the red (R) light is ultimately emitted in the emission area EA of the first pixel region SP1, the green (G) light is ultimately emitted in the emission area EA of the second pixel region SP2, and the blue (B) light is ultimately emitted in the emission area EA of the third pixel region SP3. In addition, no light is emitted in the non-emission areas NEAs of the first to third pixel regions SP1, SP2 and SP3.

The emission wavelengths of the perovskite particles 182a, 184a, 186a, 186b and 192 can be determined by the linkages among the bivalent metal cation (M in Chemical Formulae 1 to 6) and the halide anion (Cl, Br, I or combinations thereof), and the emission colors of the perovskite particles 182a, 184a, 186a, 186b and 192 can be adjusted by substitutions of the halogen atoms (halide anions). In addition, each of the perovskite particles 182a, 184a, 186a, 186b and 192 has beneficial color purity owing to narrow full-width at half maximum (FWHM, about 10 to about 25 nm), and shows beneficial luminous efficiency. The light emitting display device 100 with beneficial luminance and color gamut can be realized by introducing the perovskite particles 182a, 184a, 186a, 186b and 192 with different halogen atom compositions to the color conversion layers 182, 184 and 186 and the light blocking layer 190.

It is possible to synthesize perovskite particles 182a, 184a, 186a, 186b and 192 emitting light at different wavelength ranges with different color lights by adjusting the composition ratio of each component, and the types and composition ratios of the halogen (X) in the perovskite particles 182a, 184a, 186a, 186b and 192. In particular, because the perovskite structure forms a stable lattice structure, the color conversion layer 180 and the light blocking layer 190 comprising the perovskite particles 182a, 184a, 186a, 186b and 192 have a very stable crystal structure and improve their luminous efficiency. Additionally, a black light blocking layer 190 is disposed in the non-emission area NEA to prevent reflection by external light and improve visibility of the light emitting display device 100.

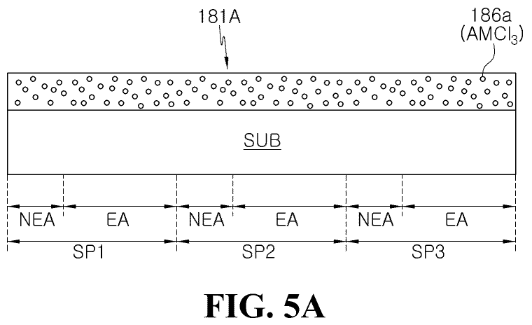

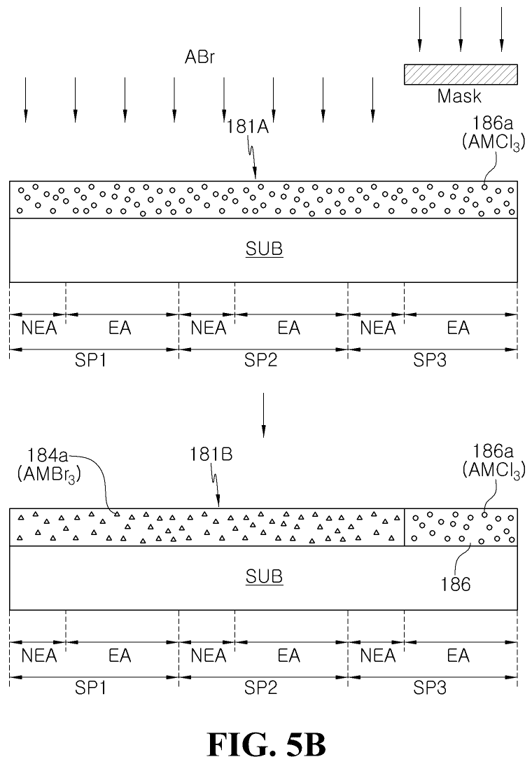

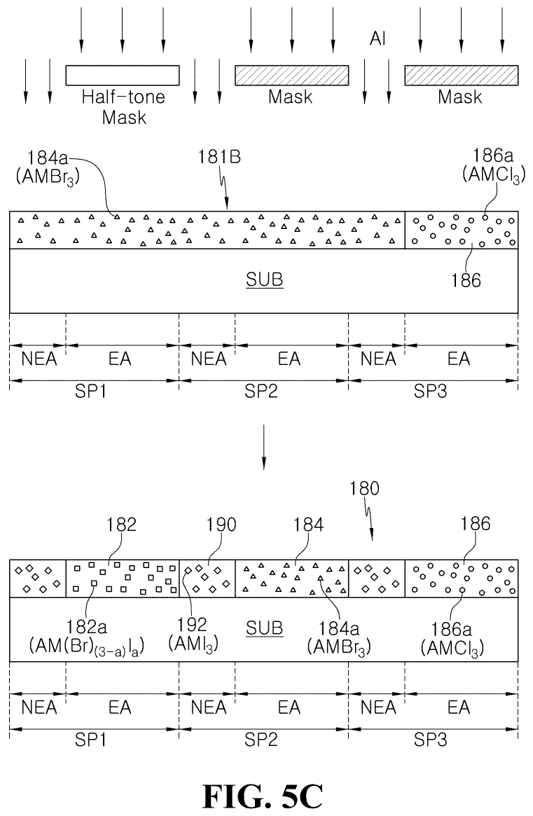

A process of manufacturing the color conversion layer 180 and the light blocking layer 190 will be described in more detail. FIGS. 5A to 5C are schematic drawings illustrating a process of color conversion layers and light blocking layers comprising perovskite particles with various or different halogen compositions in accordance with an embodiment of the present disclosure.

As illustrated in FIG. 5A, the third perovskite particle 186a (AMCl₃) is coated on an entire surface of a substrate SUB so that a perovskite film 181A is disposed on the substrate SUB. The process of coating the perovskite film 181A consisting of the third perovskite particle 186a (AMCl₃) on the substrate SUB is not limited to a particular method. For example, any solution process such as a spin coating, a drop coating a dip coating, a spray coating, a roll coating, a flow coating, a casting process, a screen printing, an inkjet printing and/or combinations thereof can be used to coat the third perovskite particle 186a on the substrate SUB. In this case, the perovskite film 181A comprising the third perovskite particle 186a (AMCl₃) of transparent or white luminescent particle is disposed on the entire surface of the first to third pixel regions SP1, SP2 and SP3 of the substrate SUB.

Next, a photolithography process using a halide precursor ABr (A is defined as in Chemical Formulae 1 to 6) comprising bromine is performed on the perovskite film 181A. As illustrated in FIG. 5B, the photolithography process such as an exposure process and a development process can be performed while the emission area EA of the third pixel region SP3 of the blue (B) pixel region is covered with a mask, and the remaining entire areas are exposed in a bromine-containing precursor ABr atmosphere. For example, the development process can be performed with a non-polar solvent.

The third color conversion layer 186 comprising the third perovskite particle 186a (AMCl₃) is disposed in the emission area EA of the third pixel region SP3 covering with the mask among the perovskite film 180A. On the contrary, electrons of the third perovskite particle 186a (AMCl₃) reacts with the halide precursor ABr in the remaining areas of the perovskite film 181A except for the emission area EA of the third pixel region SP3.

As the halide precursor ABr reacts with the third perovskite particle 186a (AMCl₃), the halide exchange or anion exchange reaction as represented by the following Reaction Formula 1 is occurred. Accordingly, the third perovskite particle 186a (AMCl₃) is converted to the second perovskite particle 184a (AMBr₃) emitting green (G) light by the following Reaction Formula 1 in the remaining areas except for the emission area EA of the third pixel region SP3.

AMCl*₃+ABr+hv,AMCl₃+ABr→AMBr₃ [Reaction Formula 1]

Accordingly, a perovskite film 181B where the emission area EA of the third pixel region SP3 includes the third perovskite particle 186a (AMCl₃) and the remaining areas except for the emission area of the third pixel region SP3 includes the converted second perovskite particle 184a (AMBr₃) is disposed on the substrate SUB.

Next, another photolithography process using a halide precursor AI (A is defined as in Chemical Formulae 1 to 6) comprising iodine is performed on the perovskite film 181B comprising the third perovskite particle 186a (AMCl₃) and the second perovskite particle 184a (AMBr₃). As illustrated in FIG. 5C, the photolithography process such as an exposure process and a development process can be performed while the emission area EA of the second pixel region SP2 and the emission area EA of the third pixel region SP3 are covered with a mask, the emission area EA of the first pixel region SP1 is covered with a semi-transmissive mask (e.g., half-tone mask with about half light transmissivity as the mask), and the remaining entire areas are exposed in an iodine-containing precursor AI. As described in FIG. 5B, the development process can be performed with a non-polar solvent.

The second color conversion layer 184 comprising the second perovskite particle 184a (AMBr₃) is disposed correspondingly to the emission area EA of the second pixel region SP2 because no halide exchange reaction is occurred in the emission area EA of the second pixel region SP2 covering with the mask among the perovskite film 181B. The third color conversion layer 186 comprising the third perovskite particle 186a (AMCl₃) can be maintained correspondingly to the emission area EA of the third pixel region SP3 because no halide exchange reaction is also occurred in the emission area EA of the third pixel region SP3.

On the contrary, as halide exchange reaction represented by the following Reaction Formula 2 is occurred between the second perovskite particle 184a (AMBr₃) and the halide precursor AI in the area not covered with the mask, that is, in the non-emission areas NEAs of the first to third pixel regions SP1, SP2 and SP3, the second perovskite particle 184a (AMB₃) is converted to the fifth perovskite particle 192 (AMI₃) of black particle in the non-emission areas NEAs of the first to third pixel regions SP1, SP2 and SP3.

AMBr*₃+AI+hv,AMBr3+AI→AMI₃ [Reaction Formula 2]

In addition, as partial halide exchange reaction represented by the following Reaction formula 3 is occurred between the second perovskite particle 184a (AMBr₃) and the halide precursor AI in the area covered with the semi-transmissive mask, that is, in the emissive area EA of the first pixel region SP1, the second perovskite particle 184a (AMBr₃) is converted to the first perovskite particle 182a (AMBr₍₃₋ₐ₎Iₐ) of red (R) particle in the emission area (EA) of the first pixel region SP1.

AMBr*₃+AI+hv,AMBr₃+AI→AMBr₍₃₋ₐ₎Iₐ [Reaction Formula 3]

The first color conversion layer 182 comprising the first perovskite particle 182a (AMBr₍₃₋ₐ₎I ₐ) emitting red (R) color light is disposed correspondingly to the emission area EA) of the first pixel region SP1 using the halide exchange reactions among perovskite particles. The second color conversion layer 184 comprising the second perovskite particle 184a (AMBr₃) emitting green (G) color light is disposed correspondingly to the emission area EA of the second pixel region. The third color conversion layer 186 comprising the third perovskite particle 186a (AMCl₃) transparent or emitting white (W) color light is disposed correspondingly to the emission area EA of the third pixel region SP3. The light blocking layer 190 comprising the fifth perovskite particle 192 (AMI₃) of black (B) color is disposed respectively to the non-emission areas NEAs of the first to third pixel regions SP1, SP2 and SP3.

In another embodiment, a barrier buffer layer can be deposited and disposed on the color conversion layers 182, 184 and 186 and the light blocking layer 190 using inorganic insulating material such as silicon oxide (SiOₓ) (0<X≤2).or silicon nitride (SiNₓ) (0<X≤2).

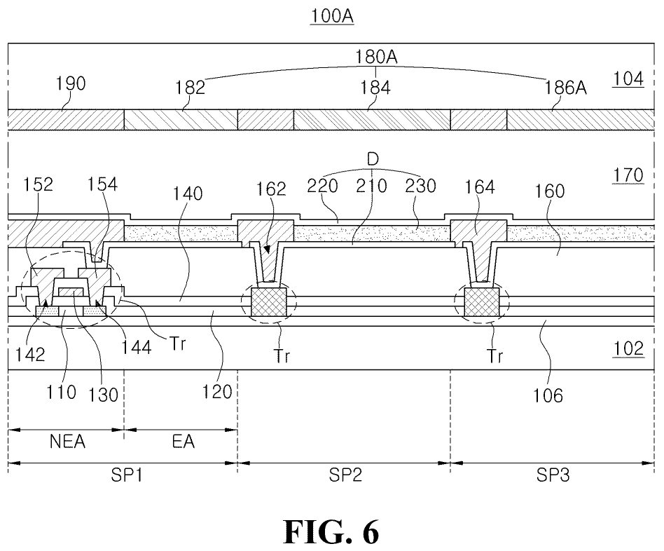

In the above embodiment, the light emitting display device 100 comprising the LED D emitting white (W) light. A light emitting diode can emit blue (B) light. FIG. 6 illustrates a cross-sectional view of a light emitting display device in accordance another embodiment of the present disclosure.

As illustrated in FIG. 6, a light emitting display device 100A in accordance with another embodiment of the present disclosure comprises a first substrate 102 and a second substrate 104 each of which defines a first pixel region SP1, a second pixel region SP2 and a third pixel region SP3. Each of the first to third pixel regions SP1, SP2 and SP3 can have an emission area EA and a non-emission area NEA. The light emitting display device 100A further comprises a thin film transistor Tr disposed on the first substrate 102 in each of the non-emission areas NEAs of the first to third pixel regions SP1, SP2 and SP3, and a light emitting diode (LED) D disposed correspondingly to each of the emission areas EAs of the first to third pixel regions SP1, SP2 and SP3, and connected to the thin film transistor Tr.

The light emitting display device 100A comprises a color conversion layer 180A disposed under the second substrate 104 and disposed correspondingly to the emission area EA of the first to third pixel regions SP1, SP2 and SP3. The color conversion layer 180A comprises a first color conversion layer 182 disposed correspondingly to the emission area EA of the first pixel region SP1, a second color conversion layer 184 disposed correspondingly to the emission area EA of the second pixel region SP2, and a third color conversion layer 186A disposed correspondingly to the emission area EA of the third pixel region SP3. In addition, a light blocking layer 190 is disposed respectively to the non-emission areas NEAs of the first to third pixel regions SP1, SP2 and SP3 to define the first to third pixel regions SP1, SP2 and SP3.

In this embodiment, no color filter layer is disposed in the non-emission area NEA of the third pixel region SP3. The LED D in the light emitting display device 100A emits blue (B) light. The LED D that can emit blue (B) light will be described in detail. FIG. 7 illustrates a cross-sectional view of a light emitting diode having a single emitting part in accordance with another embodiment of the present disclosure.

As illustrated in FIG. 7, a light emitting diode (LED) D2 in accordance with another embodiment comprises a first electrode 210, a second electrode 220 facing the first electrode 210, and an emissive layer 230A disposed between the first electrode 210 and the second electrode 220.

In one embodiment, the emissive layer 230A comprises an emitting material layer (EML) 640. The emissive layer 230A can further comprise at least one of a hole transport layer (HTL) 620 disposed between the first electrode 210 and the EML 640, and an electron transport layer (ETL) 660 disposed between the EML 640 and the second electrode 220. The emissive layer 230A can further comprise at least one of a hole injection layer (HIL) 610 disposed between the first electrode 210 and the HTL 620 and an electron injection layer (EIL) 670 disposed between the ETL 660 and the second electrode 220. Alternatively or additionally, the emissive layer 230A can further comprise at least one of an electron blocking layer (EBL) 630 disposed between the HTL 620 and the EML 640 and a hole blocking layer (HBL) 650 disposed between the EML 640 and the ETL 660.

The configurations of the first electrode 210, the second electrode 220 and the emissive layer 230A except the EML 640 can be identical to the corresponding configurations with referring to FIG. 3.

The EML 640 can include blue emission materials to emit blue (B) light. The EML 640 can comprise organic emission material or inorganic luminescent particles.

In one embodiment, when the EML 640 comprises organic emission material, the EML 640 can comprise a host and a blue dopant. The blue dopant can comprise at least one of blue phosphorescent material, blue fluorescent material and blue delayed fluorescent material. The host and the blue dopant can comprise the organic emission material with referring to FIG. 3.

In another embodiment, when the EML 640 comprises the inorganic luminescent particles, the EML 640 can comprise quantum dots (QDs) and/or quantum rods (QRs). The EML 640 can comprise blue quantum dots and/or blue quantum rods. The blue quantum dots and/or the blue quantum rods can have a single structure or a core/shell structure.

FIG. 8 is a schematic diagram illustrating dispositions of a light emitting diode, a color conversion layer and a color filter layer in each pixel region of the light emitting display device in accordance with another embodiment of the present disclosure.

As illustrated in FIG. 8, the LED D emits blue (B) light. Each of the first color conversion layer 182, the second color conversion layer 184 and the third color conversion layer 186A is disposed correspondingly to the emission area EA of the first to third pixel regions SP1, SP2 and SP3, respectively. The light blocking layer 190 is disposed correspondingly to the non-emission areas NEAs of the first to third pixel regions SP1, SP2 and SP3.

The first color conversion layer 182 disposed correspondingly to the emission area EA of the first pixel region SP1 of the red (R) pixel region comprises a first perovskite particle 182a (AM(Br)₍₃₋ₐ₎Iₐ) represented by Chemical Formula 2. The first perovskite particle 182a (AM(Br)₍₃₋ₐ₎Iₐ) emits red (R) light. The blue (B) light emitted from the LED D passes through the first color conversion layer 182 and emits red (R) light.

The second color conversion layer 184 disposed correspondingly to the emission area EA of the second pixel region SP2 of the green (G) pixel region comprises a second perovskite particle 184a (AMBr₃) represented by Chemical Formula 3. The second perovskite particle 184a (AMBr₃) emits green (G) light. The blue (B) light emitted from the LED D passes through the second color conversion layer 184 and emits green (G) light.

The third color conversion layer 186A disposed correspondingly to the emission area EA of the third pixel region SP3 of the blue (B) pixel region comprises a third perovskite particle 186a (AMCl₃, FIG. 3) represented by Chemical Formula 4 or a fourth perovskite particle 186b (AM(Br)₍₃₋ₐ₎Clₐ) represented by Chemical Formula 5. The third perovskite particle 186a (AMCl₃) is transparent or emits white (W) light, and the fourth perovskite particle 186b (AM(Br)₍₃₋ₐ₎Clₐ) emits blue (B) light. The blue (B) light emitted from the LED D passes through the third color conversion layer 186A and emits blue (B) light.

The light blocking layer 190 disposed correspondingly to the non-emission areas NEAs of the first to third pixel regions SP1, SP2 and SP3 comprise a fifth perovskite particle 192 (AMI₃) represented by Chemical Formula 6. The fifth perovskite particle 192 (AMI₃) is a black particle. The blue (B) light emitted from the LED D cannot pass through the light blocking layer 190.

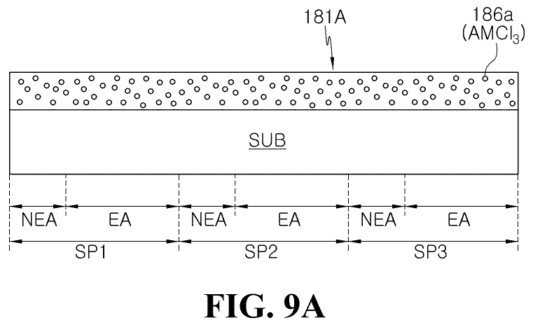

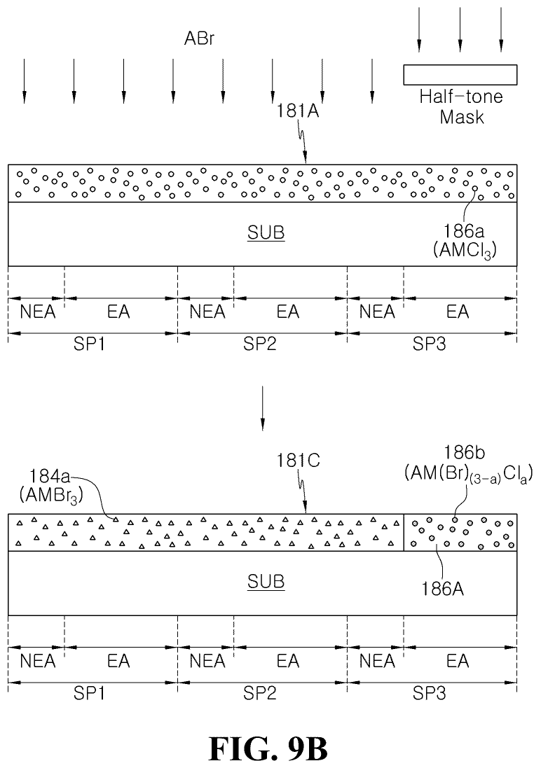

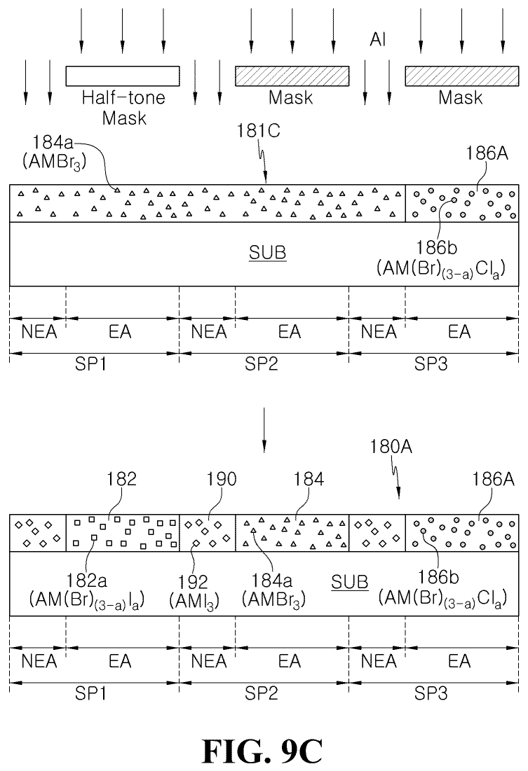

A process of manufacturing the color conversion layer 180A and the light blocking layer 190 will be described in more detail. FIGS. 9A to 9C are schematic drawings illustrating a process of color conversion layers and light blocking layers comprising perovskite particles with various or different halogen compositions in accordance with another embodiment of the present disclosure.

As illustrated in FIG. 9A, the third perovskite particle 186a (AMCl₃) is coated on an entire surface of a substrate SUB so that a perovskite film 181A is disposed on the substrate SUB. In this case, the perovskite film 181A comprising the third perovskite particle 186a (AMCl₃) of transparent or white luminescent particle is disposed on the entire surface of the first to third pixel regions SP1, SP2 and SP3 of the substrate SUB.

Next, a photolithography process using a halide precursor ABr (A is defined as in Chemical Formulae 1 to 6) comprising bromine is performed on the perovskite film 181A. As illustrated in FIG. 9B, the photolithography process such as an exposure process and a development process can be performed while the emission area EA of the third pixel region SP3 of the blue (B) pixel region is covered with a semi-transmissive mask (e.g., a half-tone mask), and the remaining entire areas are exposed in a bromine-containing precursor ABr atmosphere.

As a partial halide exchange reaction represented by the following Reaction Formula 4 is occurred between the third perovskite particle 186a (AMCl₃) and the halide precursor ABr in the emission area EA of the third pixel region SP3, the third perovskite particle 186a (AMCl₃) in the emission area EA of the third pixel region SP3 is converted to the fourth perovskite particle 186b (AM(Br)₍₃₋ₐ₎Clₐ) that emits blue (B) light.

AMCl*₃+ABr+hv,AMCl₃+ABr→AMBr₍₃₋ₐ₎Clₐ [Reaction Formula 4]

On the contrary, the halide exchange reaction represented by the Reaction Formula 1 is occurred between the third perovskite particle 186a (AMCl₃) and the halide precursor ABr in the remaining areas except for the emission area EA of the third pixel region SP3, so that the third perovskite particle 186a (AMCl₃) is converted to the second perovskite particle 184a (AMBr₃) in the remaining areas except for the emission area EA of the third pixel region SP3.

Accordingly, a perovskite film 181C where the emission area EA of the third pixel region SP3 includes the converted fourth perovskite particle 186b (AM(Br)₍₃₋ₐ₎Clₐ) and the remaining areas except for the emission area EA of the third pixel region SP3 includes the converted second perovskite particle 184a (AMBr₃) is disposed on the substrate SUB.

Next, another photolithography process using a halide precursor (AI, A is defined as in Chemical Formulae 1 to 6) comprising iodine is performed on the perovskite film 181C comprising the fourth perovskite particle 186b (AM(Br)₍₃₋ₐ₎Clₐ) and the second perovskite particle 184a (AMBr₃). As illustrated in FIG. 9C, the photolithography process such as an exposure process and a development process can be performed while the emission area EA of the second pixel region SP2 and the emission area EA of the third pixel region SP3 are covered with a mask, the emission area EA of the first pixel region SP1 is covered with a semi-transmissive mask (e.g., a half-tone mask), and the remaining entire areas are exposed in an iodine-containing precursor AI.

The second color conversion layer 184 comprising the second perovskite particle 184a (AMBr₃) is disposed correspondingly to the emission area EA of the second pixel region SP2. The third color conversion layer 186 comprising the fourth perovskite particle 186b (AM(Br)₍₃₋ₐ₎Clₐ) can be disposed correspondingly to the emission area EA of the third pixel region SP3.

In addition, as the partial halide exchange reaction represented by the Reaction Formula 3 is occurred between the second perovskite particle 184a (AMBr₃) and the halide precursor AI in the emission area EA of the first pixel region SP1 covered with the semi-transmissive mask, the second perovskite particle 184a (AMBr₃) is converted to the first perovskite particle 182a (AMBr₍₃₋ₐ₎Iₐ) of red (R) particle in the emission area (EA) of the first pixel region SP1. The first color conversion layer 182 comprising the first perovskite particle 182a (AM(Br)₍₃₋ₐ₎Iₐ) is disposed in the emission area EA of the first pixel region SP1.

On the contrary, as halide exchange reaction represented by the Reaction Formula 2 is occurred between the second perovskite particle 184a (AMBr₃) and the halide precursor AI in the area not covered with the mask or the semi-transmissive mask, that is, in the non-emission areas NEAs of the first to third pixel regions SP1, SP2 and SP3, the second perovskite particle 184a (AMBr₃) is converted to the fifth perovskite particle 192 (AMI₃) of black particle in the non-emission areas NEAs of the first to third pixel regions SP1, SP2 and SP3.

In FIGS. 9B and 9C, the third perovskite particle 186a (AMCl₃) is converted to the fourth perovskite particle 186b (AM(Br)₍₃₋ₐ₎Clₐ) by the photolithography process using the semi-transmissive mask covering the emission area EA of the third pixel region SP3. In another embodiment, the third perovskite particle 186a (AMCl₃) cannot be converted to the fourth perovskite particle 186b (AM(Br)₍₃₋ₐ₎Clₐ) by the photolithography process using the mask covering the emission area EA of the third pixel region SP3 as illustrated in FIGS. 5B and 5C.

In FIGS. 2 to 9C, the light generated in the emissive layer 230 or 230A of the LED D is released outwardly through the second electrode 220, the color conversion layer 180 or 180A, and the second substrate 104. In other words, the light emitting display device 100 or 100A in FIGS. 2 and 6 is a top-emission type. Alternatively, the light emitting display device 100 or 100A can be a bottom emission type (FIG. 10) where the light generated at the emissive layer 230 or 230A can be released outwardly through the first electrode 210 and the first substrate 102. In this case, the color conversion layer 180 or 180A and the light blocking layer 190 can be disposed between the LED D and the first substrate 102.

A light emitting display device can further comprise a fourth pixel region. FIG. 10 illustrates a cross-sectional view of a light emitting diode having multiple emitting parts in accordance with another embodiment of the present disclosure.

As illustrated in FIG. 10, a light emitting display device 100B in accordance with another embodiment of the present disclosure comprises a first substrate 102 and a second substrate 104 each of which defines a first pixel region SP1, a second pixel region SP2, a third pixel region SP3 and a fourth pixel region SP4. Each of the first to fourth pixel regions SP1, SP2, SP3 and SP4 can have an emission area EA and a non-emission area NEA. For example, the first pixel region SP1 can be a red (R) pixel region, the second pixel region SP2 can be a green (G) pixel region, the third pixel region SP3 can be a blue (B) pixel region and the fourth pixel region SP4 can be a white (W) pixel region.

The light emitting display device 100B further comprises a thin film transistor Tr disposed on the first substrate 102 in each of the non-emission areas NEAs of the first to fourth pixel regions SP1, SP2, SP3 and SP4, and a light emitting diode (LED) D disposed correspondingly to each of the emission areas EAs of the first to fourth pixel regions SP1, SP2, SP3 and SP4, and connected to the thin film transistor Tr.

In addition, the light emitting display device 100B can comprise a color filter layer 172 disposed correspondingly to the emission area EA of the third pixel region SP3 between the LED D and the first substrate 102. The color filter layer 172 can comprise blue colorant. In certain embodiment, the color filter layer 172 can be omitted.

The light emitting display device 100B comprises a color conversion layer 180B disposed correspondingly to each of the emission areas EAs of the first to fourth pixel regions SP1, SP2, SP3 and SP4 between the first substrate 102 and the LED D. The color conversion layer 180B comprises a first color conversion layer 182 disposed correspondingly to the emission area EA of the first pixel region SP1, a second color conversion layer 184 disposed correspondingly to the emission area EA of the second pixel region SP2, a third color conversion layer 186 disposed correspondingly to the emission area EA of the third pixel region SP3, and a fourth color conversion layer 188 disposed correspondingly to the emission area EA of the fourth pixel region SP4. In addition, a light blocking layer 190 is disposed correspondingly to the non-emission areas NEAs of the first to fourth pixel regions SP1, SP2, SP3 and SP4 to define the first to fourth pixel regions SP1, SP2, SP3 and SP4.

The LED D emits white (W) light. As an example, the LED D can have, but is not limited to, a tandem structure as illustrated in FIG. 3. In FIG. 10, the white (W) light emitted from the LED D is released outwardly through the first electrode 210, the color filter layer 172, the color conversion layer 180B and the first electrode 210. In other words, the light emitting display device 100B is a bottom-emission type. Alternatively, the light emitting display device 100B can be a top-emission type (FIGS. 2 and 6).

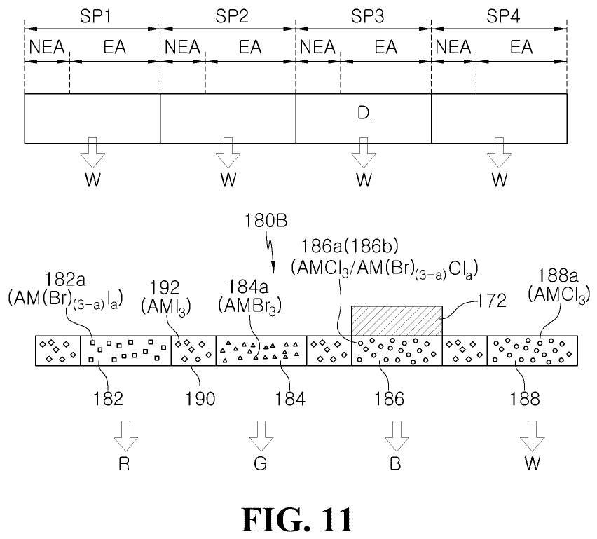

FIG. 11 is a schematic diagram illustrating dispositions of a light emitting diode, a color conversion layer and a color filter layer in each pixel region of the light emitting display device in accordance with another embodiment of the present disclosure.

As illustrated in FIG. 11, the LED D emits white (W) light. Each of the first color conversion layer 182, the second color conversion layer 184, the third color conversion layer 186 and the fourth color conversion layer 188 is disposed respectively to the emission area EA of the first to fourth pixel regions SP1, SP2, SP3 and SP4. The light blocking layer 190 is disposed respectively to the non-emission areas NEAs of the first to fourth pixel regions SP1, SP2, SP3 and SP4.

The first color conversion layer 182 disposed respectively to the emission area EA of the first pixel region SP1 of the red (R) pixel region comprises a first perovskite particle 182a (AM(Br)₍₃₋ₐ₎Iₐ) represented by Chemical Formula 2. The first perovskite particle 182a (AM(Br)₍₃₋ₐ₎Iₐ) emits red (R) light. The white (W) light emitted from the LED D passes through the first color conversion layer 182 and emits red (R) light.

The second color conversion layer 184 disposed respectively to the emission area EA of the second pixel region SP2 of the green (G) pixel region comprises a second perovskite particle 184a (AMBr₃) represented by Chemical Formula 3. The second perovskite particle 184a (AMBr₃) emits green (G) light. The white (W) light emitted from the LED D passes through the second color conversion layer 184 and emits green (G) light.

The third color conversion layer 186 disposed respectively to the emission area EA of the third pixel region SP3 of the blue (B) pixel region comprises a third perovskite particle 186a (AMCl₃) represented by Chemical Formula 4 or a fourth perovskite particle 186b (AM(Br)₍₃₋ₐ₎Clₐ) represented by Chemical Formula 5. The third perovskite particle 186a (AMCl₃) is transparent or emits white (W) light, and the fourth perovskite particle 186b (AM(Br)₍₃₋ₐ₎Clₐ) emits blue (B) light. The white (W) light emitted from the LED D passes through the third color conversion layer 186 and emits blue (B) light.

The fourth color conversion layer 188 disposed respectively to the emission area EA of the fourth pixel region SP4 of the white (W) pixel region comprises a third perovskite particle 186a (AMCl₃) represented by Chemical Formula 4. The third perovskite particle 188a (AMCl₃) is transparent or emits white (W) light. The white (W) light emitted from the LED D passes through the fourth color conversion layer 188 and emits white (W) light.

The light blocking layer 190 disposed respectively to the non-emission areas NEAs of the first to fourth pixel regions SP1, SP2, SP3 and SP4 comprise a fifth perovskite particle 192 (AMI₃) represented by Chemical Formula 6. The fifth perovskite particle 192 (AMI₃) is a black particle. The white (W) light emitted from the LED D cannot pass through the light blocking layer 190.

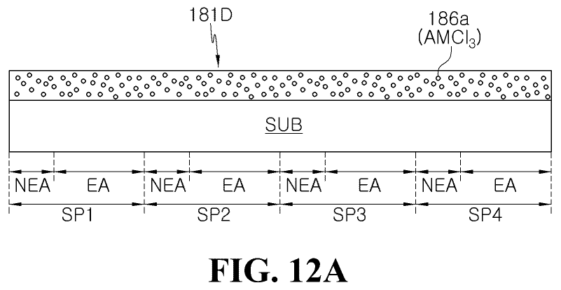

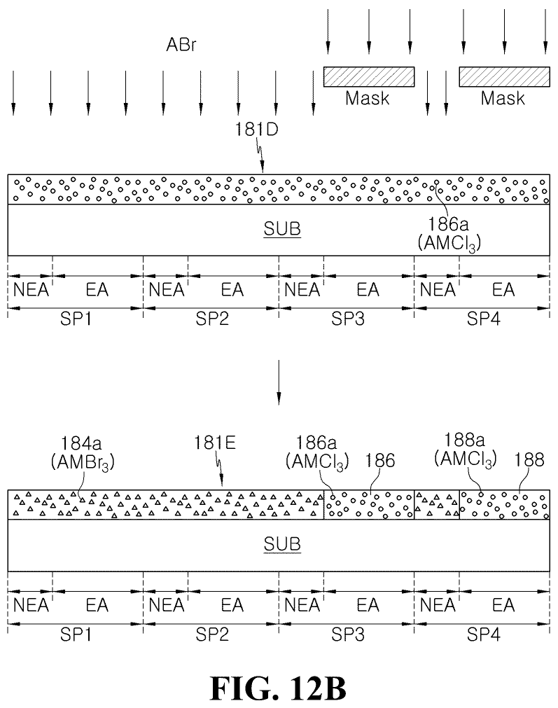

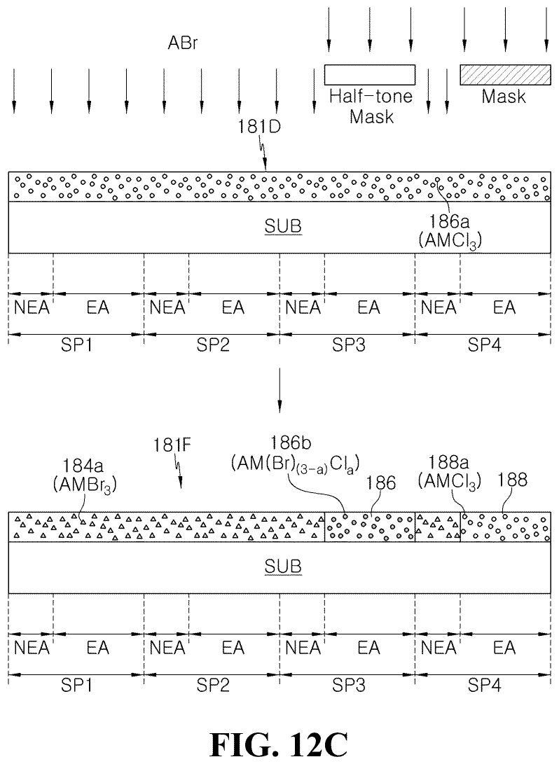

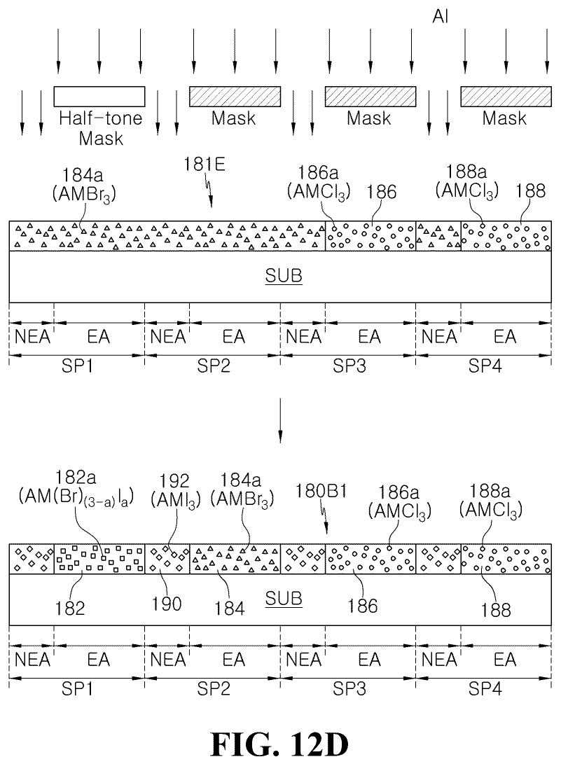

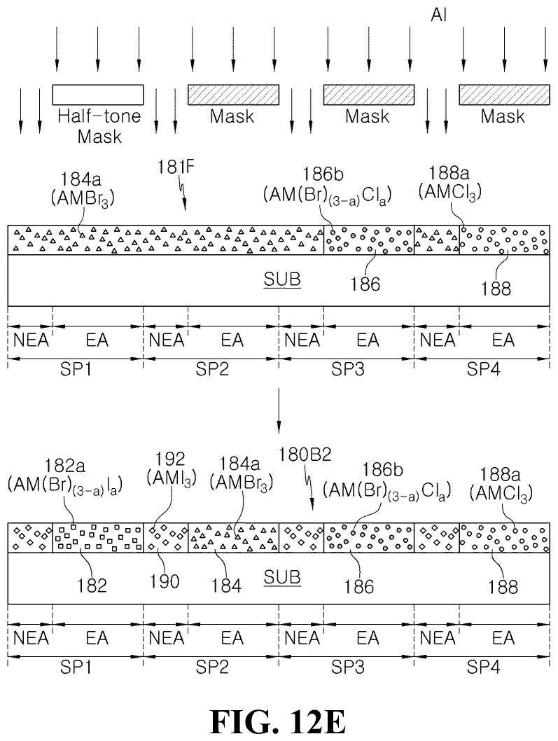

A process of manufacturing the color conversion layer 180A and the light blocking layer 190 will be described in more detail. FIGS. 12A to 12C are schematic drawings illustrating a process of color conversion layers and light blocking layers comprising perovskite particles with various or different halogen compositions in accordance with another embodiment of the present disclosure.

As illustrated in FIG. 12A, the third perovskite particle 186a or 188a (AMCl₃) is coated on an entire surface of a substrate SUB so that a perovskite film 181D is disposed on the substrate SUB. In this case, the perovskite film 181D comprising the third perovskite particle 186a (AMCl₃) of transparent or white luminescent particle is disposed on the entire surface of the first to fourth pixel regions SP1, SP2, SP3 and SP4 of the substrate SUB.

Next, a photolithography process using a halide precursor ABr (A is ng defined in Chemical Formulae 1 to 6) comprising bromine is performed on the perovskite film 181D.

In one embodiment, as illustrated in FIG. 12B, the photolithography process such as an exposure process and a development process can be performed while both the emission area EA of the third pixel region SP3 of the blue (B) pixel region and the emission area EA of the fourth pixel region SP4 of the white (W) pixel region are covered with a mask, and the remaining entire areas are exposed in a bromine-containing precursor ABr atmosphere.

In this case, the third color conversion layer 186 comprising the third perovskite particle 186a (AMCl₃) and the fourth color conversion layer 188 comprising the third perovskite particle 188a (AMCl₃) are disposed correspondingly to each of the emission area EA of the third pixel region SP3 and the emission area EA of the fourth pixel region SP4, respectively. On the contrary, halide exchange reaction represented by Reaction Formula 1 is occurred in the remaining areas except for the emission areas EAs of the third pixel region SP3 and the fourth pixel region SP4 among the perovskite film 181D. Accordingly, the third perovskite particle 186a (AMCl₃) is converted to the second perovskite particle 184a (AMBr₃) in the remaining areas except for the emission areas EAs of the third pixel region SP3 and the fourth pixel region SP4.

Accordingly, a perovskite film 181E where each of the emission areas EAs of the third pixel region SP3 and the fourth pixel region SP4 includes the third perovskite particle 186a or 188a (AMCl₃) and the remaining areas except for the emission areas EAs of the third pixel region SP3 and the fourth pixel region SP4 includes the converted second perovskite particle 184a (AMBr₃) is disposed on the substrate SUB.

In another embodiment, as illustrated in FIG. 12C, the photolithography process such as an exposure process and a development process can be performed while the emission area EA of the third pixel region SP3 of the blue (B) pixel region is covered with the semi-transmissive mask (e.g., half-tone mask), the emission area EA of the fourth pixel region SP4 of the white (W) pixel region is covered with the mask, and the remaining entire areas are exposed in a bromine-containing precursor ABr atmosphere.

In this case, as the partial halide exchange reaction represented by Reaction Formula 4 is occurred between the third perovskite particle 186a (AMCl₃) and the halide precursor ABr in the emission area EA of the third pixel region SP3 with covering the semi-transmissive mask among the perovskite film 180D, the third color conversion layer 186 comprising the converted fourth perovskite particle 186b (AM(Br)₍₃₋ₐ₎Clₐ) is disposed correspondingly to the emission area EA of the third pixel region SP3. As no halide exchange reaction is occurred in the emission area EA of the fourth pixel region SP4 with covering with the mask among the perovskite film 181D, the fourth color conversion layer 188 comprising the non-converted third perovskite particle 188a (AMCl₃) is disposed correspondingly to the emission area EA of the fourth pixel region SP4.

On the contrary, halide exchange reaction represented by Reaction Formula 1 is occurred in the remaining areas except for the emission areas EAs of the third pixel region SP3 and the fourth pixel region SP4 among the perovskite film 181D. Accordingly, the third perovskite particle 186a (AMCl₃) is converted to the second perovskite particle 184a (AMBr₃) emitting green (G) light in the remaining areas except for the emission areas EAs of the third pixel region SP3 and the fourth pixel region SP4.

Accordingly, a perovskite film 181F where each of the emission areas EAs of the third pixel region SP3 and the fourth pixel region SP4 includes the fourth perovskite particle 186b (AM(Br)₍₃₋ₐ₎Clₐ) and the third perovskite particle 188a (AMCl₃), respectively, and the remaining areas except for the emission areas EAs of the third pixel region SP3 and the fourth pixel region SP4 includes the converted second perovskite particle 184a (AMBr₃) is disposed on the substrate SUB.

Next, another photolithography process using a halide precursor (AI, A is as defined in Chemical Formulae 1 to 6) comprising iodine is performed on the perovskite film 181E or 181F comprising the second to fourth perovskite particles 184a, 186a/188a and 186b. In one embodiment, in case inducing first halide exchange reaction under the exposure process and the development process as illustrated in FIG. 12B, the second photolithography process such as the second exposure process and the development process can be performed while the emission areas EAs of the second to fourth pixel regions SP2, SP3 and SP4 are covered with the mask, the emission area EA of the first pixel region SP1 is covered with the semi-transmissive mask (e.g., half-tone mask), and the remaining areas are exposed in an iodine-containing precursor AI, as illustrated in FIG. 12D.

The second color conversion layer 184 comprising the second perovskite particle 184a (AMBr₃) is disposed correspondingly to the emission area EA of the second pixel region SP2 covered with mask among the perovskite film 181E. In addition, each of the third color conversion layer 186 and the fourth color conversion layer 188, which includes the third perovskite particles 186a and 188a (AMCl₃), respectively, is disposed correspondingly to the emission area EA of the third pixel region SP3 and the emission area EA of the fourth pixel region SP4, respectively, among the perovskite film 181E. In addition, the first color conversion layer 182 comprising the converted first perovskite particle 182a (AM(Br)₍₃₋ₐ₎Iₐ) is disposed correspondingly to the emission area EA of the first pixel region SP1 covered with the semi-transmissive mask among the perovskite film 181E.

In another embodiment, in case inducing first halide exchange reaction under the exposure process and the development process as illustrated in FIG. 12C, the second photolithography process such as the second exposure process and the development process can be performed while the emission areas EAs of the second to fourth pixel regions SP2, SP3 and SP4 are covered with the mask, the emission area EA of the first pixel region SP1 is covered with the semi-transmissive mask (e.g., half-tone mask), and the remaining areas are exposed in an iodine-containing precursor AI, as illustrated in FIG. 12E.

The second color conversion layer 184 comprising the second perovskite particle 184a (AMBr₃) is disposed in the emission area EA of the second pixel region SP2 covered with mask among the perovskite film 181F. In addition, the third color conversion layer 186 comprising the fourth perovskite particle 186b (AM(Br)₍₃₋ₐ₎Clₐ) is disposed in the emission area EA of the third pixel region SP3 covered with the mask among the perovskite film 181F. The fourth color conversion layer 188 comprising the third perovskite particle 188a (AMCl₃) is disposed in the emission area EA of the fourth pixel region SP4 covered with the mask among the perovskite film 181F. In addition, the first color conversion layer 182 comprising the converted first perovskite particle 182a (AM(Br)₍₃₋ₐ₎Iₐ) is disposed respectively to the emission area EA of the first pixel region SP1 covered with the semi-transmissive mask among the perovskite film 181F.

Perovskite particles 182a, 184a, 186a, 186b, 188a and 192 with different halogen compositions are applied to the color conversion layer 180, 180A or 180B and the light blocking layer 190. The light emitting display device 100, 100A or 100B with beneficial luminance and color gamut can be realized by applying the perovskite particles having beneficial luminous efficiency. In addition, it is possible to improve visibility of the light emitting display device without disposing a polarizer by preventing reflection by external light.

### Example 1: Evaluation of Emission Colors of Perovskite Particles

### (1) Evaluation of Optical Images and Photoluminescence (PL) Image

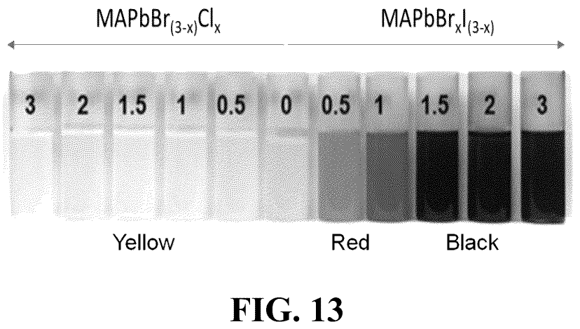

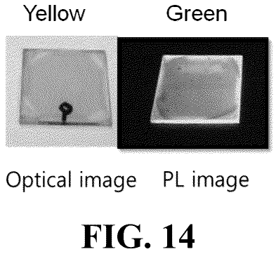

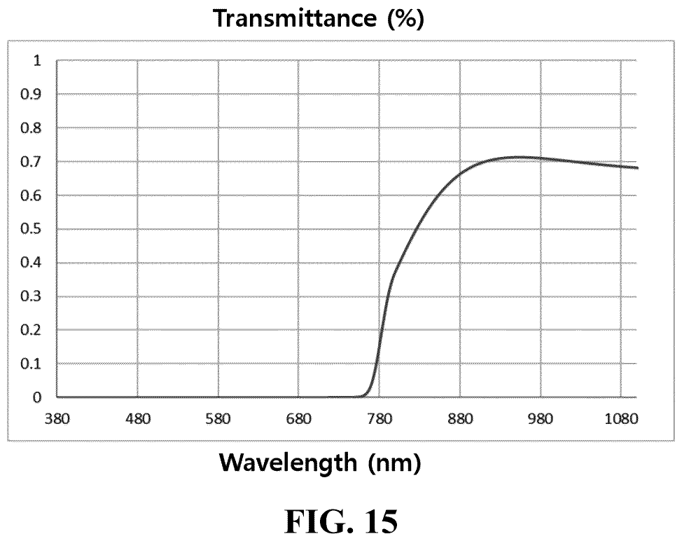

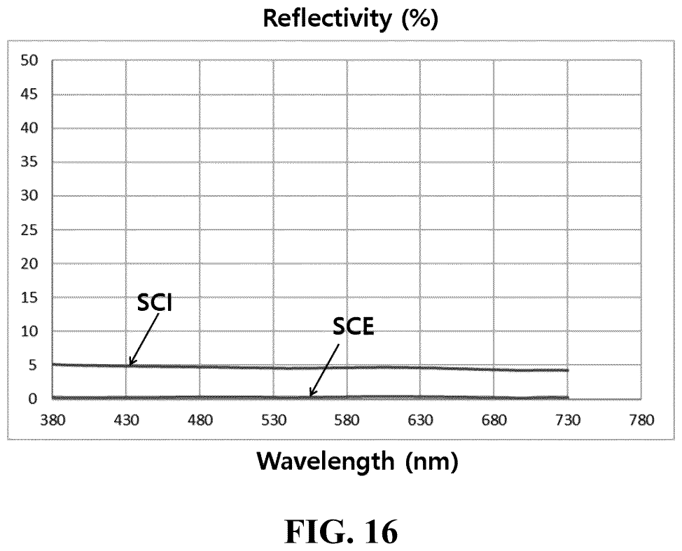

Optical images and PL images for perovskite particles with methyl ammonium (MA) as “A” in Chemical Formula 1, lead (Pb) as “M” in Chemical Formula 1, and halogen atoms with various molar ratios are evaluated. FIG. 13 illustrates optical image of the perovskite particles and FIG. 14 illustrates the optical image comparing to PL image. As illustrated in FIG. 13, the perovskite particles with various halogen molar ratios showed various optical image colors from transparent or white (MAPbCl₃) to black (MAPBI₃). As illustrated in FIG. 14, MAPbBr₃ perovskite particles emitted green color in PL spectrum.

### (2) Evaluation of Light Transmittance and Reflectivity

A film comprising black perovskite particles MAPbI₃ was fabricated and light transmittance and reflectivity for the films having MAPbI₃ was measured. FIG. 15 illustrates light transmittance for MAPbI₃ of black perovskite particles and FIG. 16 illustrates reflectivity for the perovskite particles. As illustrated in FIGS. 15 and 16, it was confirmed that the MAPbI₃ perovskite particles absorb visible lights and implement full black. In addition, the reflectivity of the MAPbI₃ based on the unit film was less than 5%.

### Example 2: Evaluation of Emission Property of Perovskite Particles

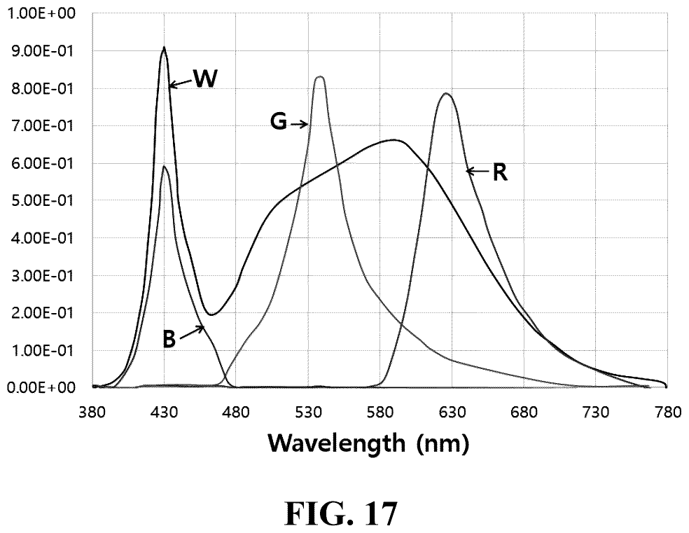

Each of a red emitting film (red color conversion layer) onto which red emitting MAPbBr₂I₁ perovskite particles are coated, a green emitting film (green color conversion layer) onto which green emitting MAPbBr₃ perovskite particles are coated, a blue emitting film (blue color conversion layer) onto which blue emitting MaBpBr_{1.5}Cl_{1.5} perovskite particles are coated, and a transparent of white emitting film onto which MAPbCl₃ perovskite particles are coated is disposed on a white emitting diode. Then, PL emission peaks for the light transmitting through the color conversion layer disposed in each pixel region was measured. FIG. 17 illustrates PL spectrum. Each of the white pixel region, blue pixel region, the green pixel region and the red pixel region used MAPbCl₃ particles, MaPbBr_{1.5}Cl_{1.5} particles, MAPbBr₃ particles and MAPbBr₂I₁ particles, respectively, as color conversion material. As illustrated in FIG. 17, each of red light, green light, blue light and white light is emitted in the red pixel region, the green pixel region, the blue pixel region and the white pixel region, respectively, by the perovskite particles with different PL emission peak.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A light emitting display device, comprising:
a first substrate having a first pixel region, a second pixel region, and a third pixel region, each of the first pixel region, the second pixel region, and the third pixel region comprising an emission area and a non-emission area;
a light emitting diode disposed in each of the first pixel region, the second pixel region, and the third pixel region, wherein the light emitting diode is located at the emission area on the first substrate;
a color conversion layer corresponding to each of the first pixel region, the second pixel region, and the third pixel region, wherein the color conversion layer is disposed on the light emitting diode or between the first substrate and the light emitting diode; and
a light blocking layer disposed at each of the non-emission area between the color conversion layer,
wherein the color conversion layer comprises a first color conversion layer disposed respectively to the emission area of the first pixel region, a second color conversion layer disposed respectively to the emission area of the second pixel region, and a third color conversion layer disposed respectively to the emission area of the third pixel region,
wherein the first color conversion layer comprises perovskite particles represented by the following Chemical Formula 2,
wherein the second color conversion layer comprises perovskite particles represented by the following Chemical Formula 3,
wherein the third color conversion layer comprises perovskite particles represented by the following Chemical Formula 4 or Chemical Formula 5, and
wherein the light blocking layer comprises perovskite particles represented by the following Chemical Formula 6:
AM(Br)₍₃₋ₐ₎Iₐ [Chemical Formula 2]
AMBr₃ [Chemical Formula 3]
AMCl₃ [Chemical Formula 4]
AM(Br)₍₃₋ₐ₎Clₐ [Chemical Formula 5]
AMI₃ [Chemical Formula 6]
wherein, in Chemical Formulae 2 to 6,
A is an organic ammonium or an alkali metal;
M is a metal selected from a bivalent transition metal, a rare earth metal, an alkaline earth metal, Pb, Sn, Ge, Ga, In, Al, Sb, Bi, Po, and combinations thereof; and
0<a<3.

2. The light emitting display device of claim 1, wherein the light emitting diode emits white light.

3. The light emitting display device of claim 2, wherein the light emitting display device further comprises a color filter layer, wherein the color filter layer is disposed between the light emitting diode disposed at the emission area of the third pixel region and the third color conversion layer.

4. The light emitting display device of claim 2, wherein the third color conversion layer comprises the perovskite particles represented by Chemical Formula 4.

5. The light emitting display device of claim 1, wherein the first substrate further comprises a fourth pixel region.

6. The light emitting display device of claim 5, wherein the color conversion layer further comprises a fourth color conversion layer disposed respectively to an emission area of the fourth pixel region.

7. The light emitting display device of claim 6, wherein the fourth color conversion layer comprises the perovskite particles represented by Chemical Formula 4.

8. The light emitting display device of claim 1, wherein the light emitting diode emits blue light.

9. The light emitting display device of claim 8, wherein the third color conversion layer comprises the perovskite particles represented by Chemical Formula 5.

10. The light emitting display device of claim 1, wherein A in Chemical Formulae 2 to 6 comprises organic ammonium.

11. The light emitting display device of claim 1, wherein A in Chemical Formulae 2 to 6 is methyl ammonium, ethyl ammonium, formamidinium, Cs, or Rb.

12. The light emitting display device of claim 1, wherein M in Chemical Formulae 2 to 6 is Pb, Sn, or Ge.

13. The light emitting display device of claim 1, wherein the light emitting diode comprises:
a first electrode;
a second electrode facing the first electrode; and
an emissive layer disposed between the first electrode and the second electrode, wherein the emissive layer comprises at least one emitting part,
wherein each of the at least one emitting part comprises an emitting material layer.

14. The light emitting display device of claim 13, wherein the emitting material layer comprises organic emission material.

15. The light emitting display device of claim 13, wherein the emitting material layer comprises inorganic luminescent particles.

16. The light emitting display device of claim 13, wherein the emissive layer further comprises a charge generation layer between adjacent two of the at least one emitting part.

17. The light emitting display device of claim 13, wherein each of the at least one emitting part further independently comprises at least one of a hole injection layer, a hole transport layer, an electron blocking layer, a hole blocking layer, an electron transport layer, and an electron injection layer.

18. The light emitting display device of claim 1, wherein the light emitting display device further comprises a thin film transistor disposed on the first substrate corresponding to each of the first pixel region, the second pixel region and the third pixel region and connected to the light emitting diode corresponding to each of the first pixel region, the second pixel region and the third pixel region.
